(19) United States
(12) Patent Application Publication
(10) Pub. No.: US 2010/0126367 A1
(43) Pub. Date: May 27, 2010

(54) Method for etching glass or metal substrates using negative photoresist and method for fabricating cliche using the same

(76) Inventors: Ji-Su Kim, Busan (KR); Kyoung-Su Jeon, Seoul (KR); Kyung-Soo Choi, Gyeonggi-do (KR); Gi-Ra Yi, Seoul (KR); Seung-Heon Lee, Seoul (KR); Dong-Myung Shin, Daejeon Metropolitan City (KR)

Correspondence Address: MCKENNA LONG & ALDRIDGE LLP, 1900 K STREET, NW, WASHINGTON, DC, 20006, US

(21) Appl. No.: 12/451,225

(22) PCT Filed: Sep. 22, 2008
(86) PCT No.: PCT/KR2008/005639

§ 371 Date: Nov. 2, 2009

(30) Foreign Application Priority Data
Sep. 21, 2007 (KR) 10-2007-0096589

(51) Int. Cl. B41N 1/00; G03F 7/20

(52) U.S. Cl. 101/395; 430/323

(57) ABSTRACT

The present invention relates to a method for etching glass or metal using a negative photoresist and a method for fabricating a cliche using the same. In the method for etching glass or metal according to the present invention, since adhesion strength between the negative photoresist and the metal or the metal oxide is excellent, the photoresist layer is not corroded by the metal or metal oxide etching solution, it is unnecessary to produce an inverse photomask, the fabrication process is simple, and a low resolution light source such as mixed wavelength type light source is capable of being used, thus, economic efficiency is ensured.

### TECHNICAL FIELD

The present invention relates to a method for etching glass or metal using a negative photoresist and a method for fabricating a cliche using the same.

This application claims priority from Korean Patent Application No. 10-2007-0096589 filed on Sep. 21, 2007 in the KIPO, the disclosure of which is incorporated herein by reference in its entirety.

### BACKGROUND ART

Offset printing is one of methods for patterning specific electronic materials such as a conductive paste, ink having excellent optical properties and the like, and is a process that is carried out while essential parts of electronic recording/imaging/circuit devices such as circuit material or color filters for display are fabricated, and a cliche is necessary to achieve this.

Here, the cliche is a form that is fabricated so that a predetermined body is easily inserted thereinto in terms of dictionary meaning, and in the related art, it generally means a tool that includes an uneven portion for transferring a pattern of an electronic material.

A known cliche is fabricated by coating a positive photoresist on glass on which chrome is deposited, and patterning it to etch the surface of the glass to have a desired shape. However, because of the adhesion problem between the positive photoresist and the surface of chrome, there are problems in that the positive photoresist is corroded by the chrome etching solution or durability to a fluoric acid for etching glass is poor when the cliche is fabricated by using glass.

In addition, it is required that a photomask that should be formed when the positive photoresist is used is an inverse type of an etched portion of glass. Accordingly, there is a problem in that when a normal photomask is required in another process, a costly photomask should be further fabricated.

In addition, as shown in FIG. 2, the cliche should be fabricated through a complicated process including a plurality of steps. In addition, since the positive photoresist is exposed by using a laser at a single wavelength, as an exposure wavelength, mostly, deep UV such as 157 nm, 193 nm, 248 nm and the like or a single laser beam at a short wavelength such as I-line (365 nm) or G-line (436 nm) is used, thus, there is a disadvantage in that cost is high.

### DISCLOSURE

### Technical Problem

Therefore, in order to solve the above problems, it is an object of the present invention to provide an etching method, in which since adhesion strength in respects to the surface of the metal or the metal oxide is excellent, the negative photoresist that is not corroded by the metal or metal oxide etching solution used in the etching process of glass or metal is used, it is unnecessary to produce an inverse photomask, the fabrication process is simple, and a low resolution light source such as mixed wavelength type light source is capable of being used without using a single laser beam, thus, economic efficiency is ensured, and a method for fabricating a cliché using the same.

### Technical Solution

In order to accomplish the above object, the present invention provides a method for etching glass, which includes the steps of a) forming a negative photoresist layer on a metal layer or the metal oxide layer that is provided on a side of the glass; b) selectively exposing the negative photoresist layer; c) developing a non-exposed portion of the negative photoresist layer to pattern the negative photoresist layer; d) etching the metal layer or the metal oxide layer of a portion on which the negative photoresist layer patterned in step c) is not coated; and e) etching the glass of the portion on which the metal layer or the metal oxide layer patterned in step d) is not coated.

In addition, the present invention provides a method for etching a metal, which includes the steps of a) forming a negative photoresist layer on the metal; b) selectively exposing the negative photoresist layer; c) developing a non-exposed portion of the negative photoresist layer to pattern the negative photoresist layer; and d) etching the metal of a portion on which the negative photoresist layer patterned in step c) is not coated.

In addition, the present invention provides a method for fabricating a cliche using the method for etching glass or metal.

In addition, the present invention provides a cliche that is fabricated using the method for fabricating the cliche.

In addition, the present invention provides a method for using the cliche in the patterning of electronic material.

### Advantageous Effects

In a method for etching glass or metal using a negative photoresist and a method for fabricating a cliche using the same, since adhesion strength between the surface of the metal or the metal oxide and the negative photoresist is excellent, the negative photoresist is not corroded by the metal or metal oxide etching solution, it is unnecessary to produce an inverse photomask, the fabrication process is simple, and a low resolution light source such as mixed wavelength type light source is capable of being used without using a single laser beam, thus, economic efficiency is ensured.

### DESCRIPTION OF DRAWINGS

FIG. 1 is a flow chart that illustrates a method for etching glass using a negative photoresist according to the present invention;

FIG. 2 is a fow chart that illustrates a method for fabricating a cliché using a known positive photoresist;

FIG. 3 is a front picture of a cliche that is fabricated using the negative photoresist according to the present invention by using a scanning electron microscope (Hitach S-4800) (magnitude: 2200:1);

FIG. 4 is an enlarged picture that illustrates a portion indicated by a left circle of FIG. 3 (magnitude: 9000:1);

FIG. 5 is a picture of a cliche fabricated using the positive photoresist in Comparative Example (magnitude: 1000:1); and

FIG. 6 is a picture that illustrates the cliche fabricated in Example 2.

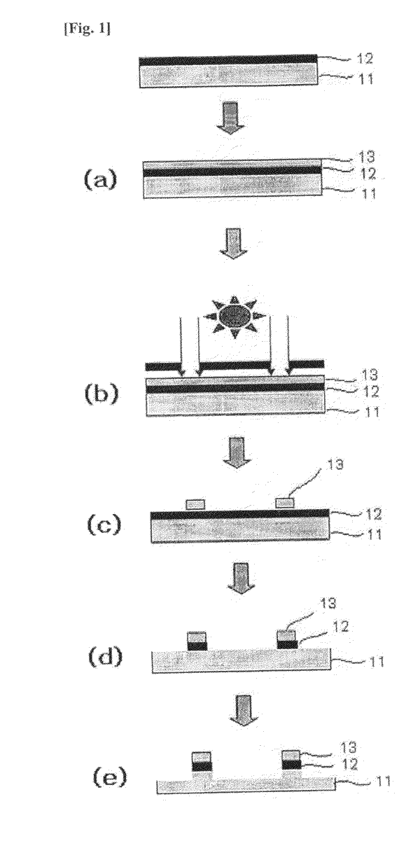

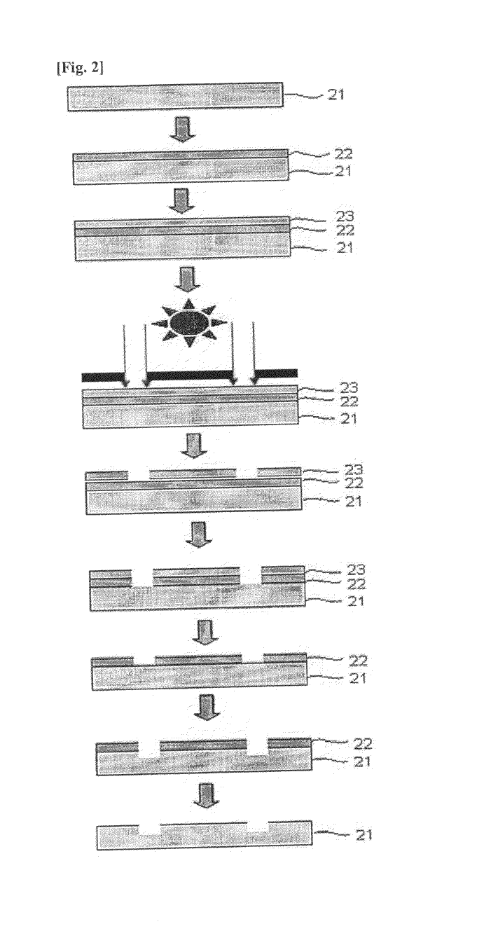

### BEST MODE

Hereinafter, the present invention will be described in detail.

The present invention relates to a photoresist that is used as a mask while a metal layer or a metal oxide layer is etched, and it is preferable that a negative photoresist is used.

The negative photoresist is a photoresist that is extensively used to fabricate a BM (black matrix) used in a current LCD color filter. Accordingly, if the negative photoresist is used to etch glass or metal, since a known color filter fabrication line using a developing solution in respects to the negative photoresist is capable of being used, the cliche is capable of being economically and efficiently fabricated. In general, an offset printing that requires the cliche is a next generation process that is used in an LCD color filter and a TFT circuit, and may reduce the cost and a tact time and be considered as an effective alternative plan in respects to the poor productivity according to the reduction of cost of LCD panel.

Therefore, the present invention suggests a novel method for fabricating a cliche that is capable of being used in offset printing. That is, as the photomask used in a known color filter process, a negative photoresist is used to efficiently fabricate a cliche having a desired embossed pattern.

First, a method for etching glass according to the present invention will be described.

In the method for etching glass according to the present invention, in step a), it is preferable that the thickness of the glass is in the range of 0.2 to 10 mm. The reason is because in the case of glass having the above thickness range, it may provide mechanical strength that is capable of enduring pressure by a blancket after the etching and the patterning of the photoresist may be easily carried out in a general LCD color filter fabrication process.

The metal may include one or more that are selected from chrome (Cr), molybdenum (Mo), and tungsten (W), but is not limited thereto. The metal oxide may include one or more that are selected from chrome oxide, molybdenum oxide, and tungsten oxide, but is not limited thereto. In the present invention, among the above examples, it is most preferable to use chrome or chrome oxide.

As the negative photoresist, a black photoresist for black matrix, a color photoresist for color filter and the like may be used. Here, as the black photoresist and the color photoresist, a mixture that includes a pigment, an alkali soluble resin binder, a multifunctional monomer having an ethylenically unsaturated double bond, a photoinitiator, a solvent, and an additive and is known in the art may be used. Preferably, there is the negative photoresist that is designed so that a photoreaction occurs in respects to mixed beams at all wavelength, which are emitted from general mercury lamps, for example, chemical products, such as HCR3 410R, HCR3 310G, HCR3 210B, BK73D1 and the like, manufactured by LG Chemicals, Co., Ltd., may be used, but are not limited thereto.

The negative photoresist layer may be formed by spin coating, slit and spin coating, slit coating, capillary coating or the like on the metal layer or the metal oxide layer, but is not limited thereto.

In step b), the selective exposing of the negative photoresist layer may be carried out by a method that is known in the art, for example, it may be carried out using a photomask, but not limited thereto.

When the negative photoresist layer is selectively exposed, a low resolution light source such as mixed wavelength including wavelengths of an I-line (365 nm), an H-line (405 nm), and a G-line (436 nm) may be used. The exposing may be carried out under the high pressure mercury lamp in which the exposure is conducted at a wavelength range of 200 to 800 nm including the above wavelength range under the intensity of 1˜100 mW/cm² for 2˜15 sec in the exposure amount of 10˜300 mJ/cm². Here, the exposure amount varies according to the sensitivity of the photoresist and preferably 200 mJ/cm².

If the wavelength in the range of 200˜300 nm is used like a known technology, since the above wavelength range is not a single wavelength but a wavelength that is formed by artificially making a wavelength range of an exposing machine narrow using a filter and the like, a kind of photoinitiator that may be included in the negative photoresist is limited, and a special apparatus such as a photofilter is required in the exposing machine. Thus, there are problems in that the process becomes cumbersome and additional cost is required.

In step c), as the developing solution that is used when the negative photoresist is developed, it is preferable that KOH, NaOH, TMAH (tetra methyl ammonium hydroxide) and the like are used.

According to the present invention, the negative photoresist starts to be cross-linked at only a portion thereof which receives UV by the component of the photoinitiator, its curing is finished after the prebaking to form a hard polymer, and when it is developed in an alkali aqueous solution, a portion of the negative photoresist, which does not receive UV, is dissolved because of a difference in solubility. Accordingly, only the portion which receives the UV light may remain to form a precise pattern.

On the other hand, if an acid aqueous solution is used as the developing solution, it dissolves the non-exposed portion of the negative photoresist and the metal film therebeneath. Thus, the portion of the negative photoresist that has reduced adhesion strength in respects to the insulating susbstrate therebeneath is removed and only the portion which receives light remains. However, the removal is not completely carried out, thus a precision pattern may not be obtained.

In step d), in the case of when the metal layer or the metal oxide layer is, for example, a chrome layer or a chrome oxide layer, as the etching solution used to etch them, a nitric acid, ceric ammonium nitrate ((NH₄)₂Ce(NO₃)₆) and the like may be used, but are not limited thereto.

In addition, in the case of when the metal layer or the metal oxide layer is, for example, a molybdenum layer or a molybdenum oxide layer, a mixture including HF and H₂O₂ mixed with each other at various ratios according to the etching rate may be used as the etching solution, but is not limited thereto.

In addition, in the case of when the metal layer or the metal oxide layer is, for example, tungsten or tungsten oxide, a fluoric acid aqueous solution including a fluoric acid (HF) and deioinized water mixed with each other in various concentrations may be used, but is not limited thereto.

In step e), as the etching solution used to etch the glass, a fluoric acid (HF) and the like may be used, but not limited thereto.

In the method for etching the glass according to the present invention, in step a), a commercial glass on which the metal layer or the metal oxide layer is provided on a side thereof such as chrome BM glass may be used, but the method may further include forming the metal layer or the metal oxide layer on a side of glass before step a). The metal layer or the metal oxide layer may be formed by using the deposition.

At this time, in order to form the metal layer or the metal oxide layer in a thin film having not more than several nm, plasma deposition, e-beam deposition, and heat deposition may be used, it is preferable that the deposition operation is carried out under a vacuum in the range of 10⁻⁴˜10⁻¹² mbar in order to protect a filament generating heat except for the plasma deposition that may be carried out under normal pressure. The deposition is carried out by hitting a meal target using nitrogen or oxygen ions that are plasmanized by electrons having high energy or by heat caused by an electronic beam focused on the metal target.

After step e), the photoresist that remains on the glass may be removed by a rework chemical, and the rework chemical is a basic solvent for removing photoresist, which is generally used to increase the yield in an LCD color filter process. For example, it is preferable to use a rework chemical in which an etching effect is increased by adding an amine-based additive, sulfuric oxides, surfactants and the like to NaOH and the like.

In addition, in the method for etching glass according to the present invention, after step e), the metal and the metal oxide remaining on the protrusions of the glass pattern may be removed by using a metal etchant used in step d). The removal of the photoresist, and the metal and the metal oxide on the protrusions of the pattern, which is disclosed in the final stage, is not a process that is necessarily carried out to fabricate the cliche, and even though an organic and inorganic substance layers are present, the function of the cliche may be maintained.

Next, the method for etching the metal according to the present invention will be described below.

The method for etching the metal includes the steps of a) forming a negative photoresist layer on the metal; b) selectively exposing the negative photoresist layer; c) developing a non-exposed portion of the negative photoresist layer to pattern the negative photoresist layer; and d) etching the metal of a portion on which the negative photoresist layer patterned in step c) is not coated.

Almost all metal such as chrome, molybdenum, tungsten and the like, which has an etching solution for patterning, may be used as the metal, but are not limited thereto. In addition, the same methods and materials as those of the method for etching glass are used, except that glass is not used.

In the present invention, in the case of when the substrate is not glass but metal, the method for etching the metal may become more simplified. After the negative photoresist is patterned, if it is exposed to the metal etching solution for a predetermined time, an uneven portion is formed on the metal and the remaining negative photoresist may be removed by using the rework chemical.

In addition, the present invention provides a method for fabricating a cliche using the method for etching glass or metal.

In addition, the present invention provides a cliche that is fabricated using the method for fabricating the cliche.

The cliche that is fabricated by using the method for etching the glass may includes a glass that has an uneven portion formed by etching, a metal layer or a metal oxide layer that is disposed on protrusions of the glass, and a negative photoresist layer that is disposed on the metal layer or the metal oxide layer, which are sequentially layered. In addition, by further removing the photoresist layer, it may include the glass having the uneven portion and the metal layer or the metal oxide layer, or by additionally removing the metal layer or the metal oxide layer, it may include only glass having the uneven portion.

In addition, the cliche that is fabricated by using the method for etching the metal may include a metal that has an uneven portion formed by etching, and a negative photoresist layer that is disposed on the metal, which are sequentially layered. In addition, by further removing the photoresist layer, it may include only the metal having the uneven portion.

In addition, the present invention provides a method for using the cliche in the patterning of an electronic material. In detail, the method may include the steps of coating an electronic material on a substrate; bringing a patterned side of the cliche into contact with the side of the substrate on which the electronic material is coated to transfer the electronic material to the cliche; and transferring the electronic material coated on the cliche to the subject print body.

At this time, the substrate may be a flat plate or a roll, and the cliche may be a flat plate or a roll.

In addition, the present invention may include the steps of filling a groove of the cliche having the groove with the electronic material, pressing a substrate on the cliche in which the electronic material is filled to transfer the electronic material filled in the groove to the substrate, and bringing the side of the substrate on which the electronic material is transferred into contact with the subject print side to transfer the electronic material on the substrate to the subject print body.

The electronic material includes optical ink, a metal solution for wiring, a conductive paste, a resist, an attachment agent, an adhesive or the like.

In addition, the print body that is obtained by transferring the electronic material on the cliche according to the present invention and printing it may be used in a color filter for TFT-LCDs, electronic circuits and the like.

Since the cliche that is fabricated by using a known positive photoresist has the good pattern straight property, the more precise resolution may be obtained as compared to the cliche that is fabricated by using the negative photoresist. In general, since the positive photoresist is exposed by using a laser at a single wavelength, scattering reflection hardly occurs on the coating side, and in the respects to the exposure wavelength, mostly, deep UV such as 157 nm, 193 nm, 248 nm and the like or a single laser beam at a short wavelength such as i-line (365 nm) or g-line (436 nm) is used, thus a ultrafine pattern having the size of not more than several hundreds nano (nm) can be obtained. Based on the same reason, since the pattern straight property ensures the reliability within ±0.5%, the pattern straight property of the cliche using the same corresponds to it. However, in the case of the positive photoresist, since it is required that only an exposing machine using the special light is used, there are disadvantages in that equipment is costly and the raw material is more expensive as compared to the negative photoresist. Thus, in a situation in which the cliche should be fabricated by applying the fabrication line of a known LCD color filter, there are many limits therein. In contrary, in the case of the negative photoresist, the developing line of a known color filter based on KOH may be used and has sufficiently excellent straight property when it is used to fabricate a cliche for LCD color filters required in a level of several tens μm or not less than 100 μm as compared to the cliche that is fabricated by using the positive resist.

### Mode for Invention

Hereinbelow, the present invention will be described in detail with reference to Examples. The present invention may, however, be embodied in many different forms and should not be construed as being limited to the Examples set forth herein. Rather, these Examples are provided to fully convey the concept of the invention to those skilled in the art.

### Example 1

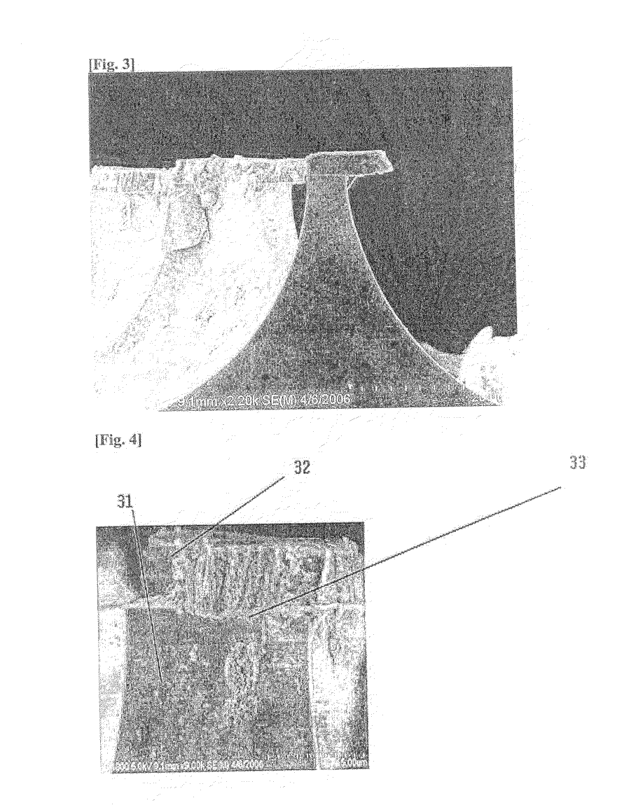

The negative photoresist (LG Chemicals, LGBK73D1) for black matrix was formed in a thickness of 2 μm on the chrome BM glass (Avatec, lot#1-060916) having the thickness of 0.5 mm by using spin coating. The formed photoresist was exposed under the high pressure mercury lamp in a light intensity of 20 mW/cm² for 10 sec in an exposure amount of 200 mJ/cuff and the exposed negative photoresist was developed by using the developing solution KOH. After the developing, only the exposed pattern portion remained on the chrome BM and the portion that was not exposed to light because it was blocked by the photomask was washed by the developing solution to exposure the chrome layer. In order to etch this chrome layer so that the glass portion was exposed, the chrome layer was etched by using the etching solution that was produced by mixing a nitric acid, ceric ammonium nitrate ((NH₄)₂Ce(NO₃)₆) and H₂O at a mixing ratio of 16:10:74. Next, the glass portion was etched by using a fluoric aqueous solution including deionized water and the fluoric acid mixed with each other at a mixing ratio of 9:1 to fabricate a cliche on which a pattern was formed. The fabricated cliche was shown in FIGS. 3 and 4.

### Comparative Example

The positive photoresist (Clariant, AZ1512) was formed in a thickness of 2 μm on the chrome BM glass (Avatec, lot#1-060916) having the thickness of 0.5 mm by using spin coating. The formed photoresist was exposed under the high pressure mercury lamp in a light intensity of 20 mW/cm² for 10 sec in an exposure amount of 200 mJ/cm² and the exposed photoresist was developed by using the developing solution 2.38% TMAH (tetramethyl ammonium hydroxide). After the developing, only the pattern portion which was blocked by the photomask remained on the chrome BM and the portion that was exposed to light was washed by the developing solution to exposure the chrome layer. In order to etch this chrome layer so that the glass portion was exposed, the chrome layer was etched by using the etching solution that was produced by mixing a nitric acid, ceric ammonium nitrate ((NH₄)₂Ce(NO₃)₆) and H₂O at a mixing ratio of 16:10:74. Next, the glass portion was etched by using a fluoric aqueous solution including deionized water and the fluoric acid mixed with each other at a mixing ratio of 9:1 to fabricate a cliche on which a pattern was formed. The fabricated cliche was shown in FIG. 5.

### Example 2

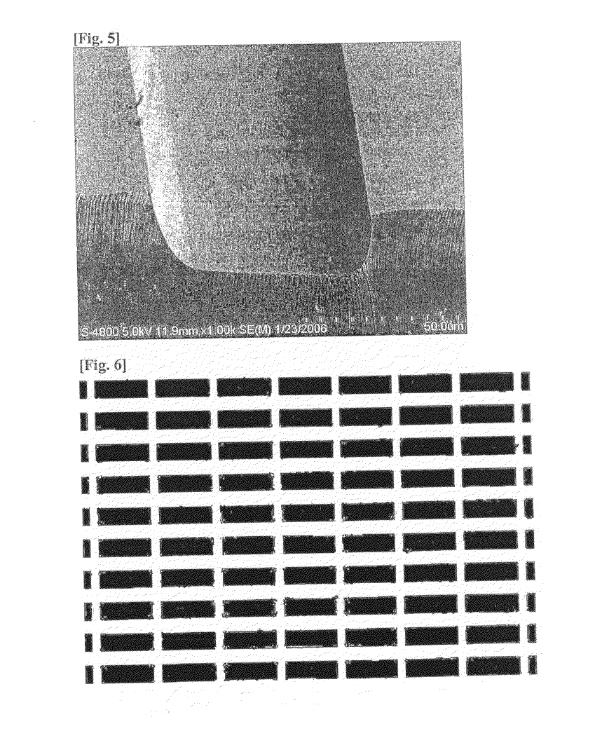

After the blue negative photoresist (LG Chemicals, HCR3 210B) for black matrix was formed in a thickness of 1.5 μm on the chrome BM glass (Avatec, lot#1-060916) having the thickness of 0.5 mm by using spin coating, the formed photoresist was exposed under the high pressure mercury lamp in a light intensity of 20 mW/cm² for 5 sec in an exposure amount of 100 mJ/cm² and the exposed negative photoresist was developed by using the developing solution TMAH (tetramethyl ammonium hydroxide). After the developing, only the exposed pattern portion remained on the chrome BM and the portion that was not exposed to light because it was blocked by the photomask was washed by the developing solution to exposure the chrome layer. In order to etch this chrome layer so that the glass portion was exposed, the chrome layer was etched by using the etching solution that was produced by mixing a nitric acid, ceric ammonium nitrate ((NH₄)₂Ce(NO₃)₆) and H₂O at a mixing ratio of 16:10:74. Next, the glass portion was etched by using a fluoric aqueous solution including deionized water and the fluoric acid mixed with each other at a mixing ratio of 9:1 to fabricate a cliche on which a pattern was formed. The fabricated cliche was shown in FIG. 6. As shown in FIG. 6, the cliche having the clean pattern is capable of being fabricated according to the present invention.

1. A method for etching glass, comprising the steps of:
a) forming a negative photoresist layer on a metal layer or the metal oxide layer that is provided on a side of the glass;
b) selectively exposing the negative photoresist layer;
c) developing a non-exposed portion of the negative photoresist layer to pattern the negative photoresist layer;
d) etching the metal layer or the metal oxide layer of a portion on which the negative photoresist layer patterned in step c) is not coated; and
e) etching the glass of the portion on which the metal layer or the metal oxide layer patterned in step d) is not coated.

2. The method for etching glass as set forth in claim 1, further comprising:
before step a), forming a metal layer or a metal oxide layer on a side of the glass.

3. The method for etching glass as set forth in claim 2, wherein before step a), the metal layer or the metal oxide layer is deposited on a side of the glass by using any one method that is selected from the group consisting of plasma deposition, e-beam deposition and heat deposition.

4. The method for etching glass as set forth in claim 1, further comprising:
after step e), removing the negative photoresist layer.

5. The method for etching glass as set forth in claim 4, further comprising:
after the step of removing the negative photoresist layer, removing the metal layer or the metal oxide layer.

6. The method for etching glass as set forth in claim 1, wherein the thickness of the glass is in the range of 0.2 to 10 mm.

7. The method for etching glass as set forth in claim 1, wherein the metal includes one or more that are selected from the group consisting of chrome, molybdenum, and tungsten.

8. The method for etching glass as set forth in claim 1, wherein the metal oxide includes one or more that are selected from the group consisting of chrome oxide, molybdenum oxide, and tungsten oxide.

9. (canceled)

10. (canceled)

11. The method for etching glass as set forth in claim 1, wherein in step b), the exposing is carried out within a wavelength range of 200 to 800 nm for 2 to 15 sec.

12. (canceled)

13. The method for etching glass as set forth in claim 1, wherein in step c), the developing is carried out using one or more developing solutions that are selected from the group consisting of KOH and NaOH.

14. The method for etching glass as set forth in claim 1, wherein in step d), the metal layer or the metal oxide layer is etched using one or more etching solutions that are selected from the group consisting of a nitric acid, seric ammonium nitrate, a solution mixture of a fluoric acid and H₂O₂, and a solution mixture of a fluoric acid and deionized water.

15. The method for etching glass as set forth in claim 1, wherein in step e), the glass is etched using the fluoric acid.

16. A method for fabricating a cliche using the method for etching the glass according to claim 1.

17. A cliche that is fabricated using the method for fabricating the cliche according to claim 16.

18. The cliche as set forth in claim 17, wherein the cliche comprises a glass that has an uneven portion formed by etching, a metal layer or a metal oxide layer that is disposed on protrusions of the glass, and a negative photoresist layer that is disposed on the metal layer or the metal oxide layer, which are sequentially layered.

19. (canceled)

20. A method for etching a metal, comprising the steps of:
a) forming a negative photoresist layer on the metal;
b) selectively exposing the negative photoresist layer;
c) developing a non-exposed portion of the negative photoresist layer to pattern the negative photoresist layer; and
d) etching the metal of a portion on which the negative photoresist layer patterned in step c) is not coated.

21. The method for etching a metal as set forth in claim 20, wherein the metal includes one or more that are selected from the group consisting of chrome, molybdenum, and tungsten.

22. A method for fabricating a cliche using the method for etching the metal according to claim 20.

23. A cliche that is fabricated using the method of fabricating the cliche according to claim 22.

24. The cliche as set forth in claim 23, wherein the cliche comprises a metal that has an uneven portion formed by etching, and a negative photoresist layer that is disposed on the metal, which are sequentially layered.
